(19) United States
(12) Patent Application Publication
(10) Pub. No.: US 2026/0239587 A1
(43) Pub. Date: Aug. 13, 2026

(54) LIQUID-BASED THERMAL MANAGEMENT SYSTEM FOR A POWER SUPPLY UNIT

(71) Applicant: VERTIV CORPORATION, Westerville, OH (US)

(72) Inventors: Rahul K. MUSALE, Pune (IN); Akshay D. SHAH, Pune (IN); Dilesh Arvind RAUT, Pune (IN)

(73) Assignee: VERTIV CORPORATION, Westerville, OH (US)

(21) Appl. No.: 19/537,819

(22) Filed: Feb. 12, 2026

(30) Foreign Application Priority Data
Feb. 12, 2025 (IN) 202511011775

(51) Int. Cl. H05K 7/20

(52) U.S. Cl. CPC H05K 7/20927; H05K 7/20272

(57) ABSTRACT

A liquid-based thermal management system for a power supply unit comprising a shelf adapted to house a power supply unit including a plurality of heat-generating components, and a liquid cooling adapter assembly thermally coupled to the shelf, comprising a thermal interface material to conduct heat to the shelf, and a plurality of liquid-carrying cooling conduits arranged on the shelf to receive the conducted heat and remove the heat using a circulating liquid coolant. The cooling conduits include an inlet configured to receive a cooled liquid coolant and an outlet configured to discharge the liquid coolant after heat absorption, wherein the liquid coolant is circulated via a pumping mechanism. The liquid cooling adapter assembly is integrated within a rectifier shelf and includes a cold plate positioned in thermal communication with the components, whereby heat generated by the components is transferred to the cold plate and removed by the flowing liquid coolant.

### CROSS-REFERENCE TO RELATED APPLICATION

This patent application claims priority to Indian Patent Application No. IN 202511011775, filed on Feb. 12, 2025, entitled “A POWER SUPPLY UNIT EQUIPPED WITH LIQUID COOLING FACILITY,” and assigned to the assignee hereof. The entire disclosure of the above application is incorporated herein by reference.

### FIELD

Embodiments of the present disclosure generally relate to the field of power electronics and thermal management, specifically to a liquid-based thermal management system for a power supply unit for efficient heat dissipation from electrical and electronic components housed within the power supply unit.

### BACKGROUND

This section provides background information related to the present disclosure which is not necessarily prior art.

Data centers form a critical backbone of modern digital infrastructure and are widely used to support a variety of services, including data storage, cloud computing, shared access to applications, secure financial transactions, and system back-up and recovery. With rapid advancements in information technology, enterprises are increasingly deploying high-performance computing systems incorporating extended memory banks, high-speed processors, and densely packed electronic components. As a result, power consumption within data centers has increased substantially.

Power supply units (PSUs) deployed in such environments are required to deliver higher power output while simultaneously meeting stringent requirements related to size, efficiency, thermal performance, and reliability. A typical PSU used in data centers includes a housing or shelf structure that supports and encloses various electrical and electronic components, such as rectifiers, converters, transformers, power semiconductor devices, control circuitry, and associated interconnections. In modular power systems, the shelf may further include one or more rectifier shelves configured to receive removable or fixed rectifier modules.

Modern design trends in PSUs emphasize increased power density by reducing the size of power conversion components while increasing operating current and switching frequency. These trends result in significant heat generation within the PSU, particularly at localized thermal hotspots associated with power semiconductor devices mounted on printed circuit boards and within rectifier shelves. The structural configuration of the PSU, including the arrangement of shelves, rectifier modules, and enclosure surfaces, often restricts airflow and limits the effectiveness of conventional cooling techniques.

Traditionally, PSUs rely on forced air-cooling mechanisms for thermal management, such as fans, vents, and heat sinks, to dissipate heat from internal components. While air cooling may be sufficient for thermal management in lower power ratings, it becomes increasingly ineffective in high-density PSUs due to constraints imposed by compact structural layouts, increased component packing, and reduced thermal conduction paths between heat-generating components and ambient air. Additionally, the reliance on high-speed fans for thermal management leads to increased power consumption, acoustic noise, and potential reliability issues due to mechanical wear.

Accordingly, there exists a need for a power supply unit having an improved structural configuration that enables efficient heat transfer from internal electrical and electronic components to a liquid cooling medium without substantially altering the overall form factor of the PSU. There is also a need for a cooling solution that can be directly integrated with the PSU shelf or rectifier shelf structure, provide a shorter and more efficient heat transfer path with fewer interfaces, and support higher power density while maintaining reliability and cost-effectiveness.

### SUMMARY

This section provides a general summary of the disclosure, and is not a comprehensive disclosure of its full scope or all of its features.

Solution to one or more drawbacks of existing technology, and additional advantages are provided through the present subject matter, including effective thermal management of power supply unit by liquid-based thermal management system. Additional features and advantages are realized through the integral structural integration of the liquid cooling adapter assembly with the power supply unit shelf using standard materials and conventional fastening techniques, thereby enabling cost-effective manufacturing, mechanical robustness, and simplified assembly. The direct thermal coupling of liquid-carrying cooling conduits or cold plates with the shelf and heat-generating components provides efficient heat removal while maintaining ease of access for installation, servicing, and replacement. Various embodiments support flexible implementation across different power supply configurations, power densities, and liquid cooling infrastructures, including externally driven or integrated circulation systems. Other embodiments employ alternative thermal interface materials, conduit geometries, and coolant flow paths to balance thermal performance, reliability, manufacturability, and scalability, thereby overcoming thermal and spatial limitations associated with conventional air-cooled power supply units.

In an embodiment, the present disclosure relates to a liquid-based thermal management system for power supply unit. The system comprises a shelf configured to house one or more power supply units, the shelf being in thermal communication with a plurality of heat-generating electrical and/or electronic components of the one or more power supply unit. The system further comprises a liquid cooling adapter assembly thermally coupled to the shelf. The liquid cooling adapter assembly comprising at least one thermal interface material disposed between at least one of the plurality of electrical and/or electronic components and the shelf, the thermal interface material being configured to conduct heat from the at least one component to the shelf. The liquid cooling adapter assembly further comprising a plurality of liquid-carrying cooling conduits arranged on the shelf and configured to receive heat conducted through the shelf and remove the heat by circulation of a liquid coolant.

In an aspect of the present disclosure, the top surface of the shelf comprises a plurality of embosses configured to secure the plurality of liquid-carrying cooling conduits to the shelf and to enhance thermal conduction between the shelf and the cooling conduits.

In an aspect of the present disclosure, the shelf is formed from a thermally conductive metal material.

In an aspect of the present disclosure, the plurality of liquid-carrying cooling conduits is mechanically retained on the shelf over the embosses using one or more fastening or clamping elements.

In an aspect of the present disclosure, the liquid coolant comprises at least one of deionized water, a mixture of water and ethylene glycol, a mixture of water and propylene glycol, mineral oils, or a dielectric fluids.

In an aspect of the present disclosure, the plurality of liquid-carrying cooling conduits is covered by a protective enclosure.

In an aspect of the present disclosure, the thermal interface material comprises double-sided thermal tape.

In an aspect of the present disclosure, the liquid-carrying cooling conduits comprises at least one inlet configured to receive a cooled liquid coolant and at least one outlet configured to discharge the liquid coolant after the liquid coolant has absorbed heat from the shelf.

In an aspect of the present disclosure, circulation of the liquid coolant through the plurality of liquid-carrying cooling conduits is established by a pumping mechanism configured to drive the liquid coolant through the at least one inlet and the at least one outlet of the liquid-carrying cooling conduits.

In another embodiment, the present disclosure relates to a liquid-based thermal management system for power supply unit. The system comprises a shelf configured to house at least one rectifier shelf including one or more power supply unit, the rectifier shelf being in thermal communication with a plurality of heat-generating electrical and/or electronic components of the one or more power supply units. The system further comprises a liquid cooling adapter assembly integrated within the at least one rectifier shelf. The liquid cooling adapter assembly comprises at least one cold plate disposed inside the rectifier shelf and positioned in thermal communication with at least one of the plurality of heat-generating electrical and/or electronic components, wherein the at least one cold plate defines one or more internal channels configured to receive and circulate a liquid coolant therethrough. Heat generated by the plurality of electrical and/or electronic components is transferred to the at least one cold plate and removed by the liquid coolant flowing through the internal channels of the cold plate.

In an aspect of the present disclosure, the at least one cold plate is positioned to be in thermal communication with the plurality of heat-generating electrical and/or electronic components through at least one thermal interface material.

In an aspect of the present disclosure, the thermal interface material comprises double-sided thermal tape.

In an aspect of the present disclosure, the liquid coolant comprises at least one of deionized water, a mixture of water and ethylene glycol, a mixture of water and propylene glycol, mineral oils, or a dielectric fluids.

In an aspect of the present disclosure, the cold plate is made up of or constructed from thermally conductive metal material.

In an aspect of the present disclosure, the one or more internal channels of the at least one cold plate include at least one inlet port configured to receive a cooled liquid coolant and at least one outlet port configured to discharge the liquid coolant after heat absorption.

In an aspect of the present disclosure, circulation of the liquid coolant through the one or more internal channels of the at least one cold plate is driven by a pumping mechanism configured to maintain continuous flow of the liquid coolant.

Further areas of applicability will become apparent from the description provided herein. The description and specific examples in this summary are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way. In the drawings:

FIG. 1 illustrates a perspective view of a proposed liquid-based thermal management system for a power supply unit, in accordance with an embodiment of the present disclosure;

FIGS. 2a and 2b illustrates a top view of a proposed liquid-based thermal management system for a power supply unit, in accordance with an embodiment of the present disclosure;

FIG. 3 illustrates a front sectional view of a proposed liquid-based thermal management system for a power supply unit, in accordance with an embodiment of the present disclosure;

FIG. 4 illustrates a perspective view of a proposed liquid-based thermal management system for a power supply unit, in accordance with another embodiment of the present disclosure; and

FIG. 5 illustrates an exploded view of a proposed liquid-based thermal management system for a power supply unit, in accordance with another embodiment of the present disclosure.

While the disclosed liquid-based thermal management system for a power supply unit is susceptible to various modifications and alternative forms, specific embodiments thereof have been shown by way of example in the drawings and are described herein in detail. The figures and written description are not intended to limit the scope of the inventive concepts in any manner. Rather, the figures and written description are provided to illustrate the inventive concepts to a person of ordinary skill in the art by reference to particular embodiments.

### DETAILED DESCRIPTION

For the purpose of promoting an understanding of the principles of the disclosure, reference will now be made to the embodiment illustrated in the figures and specific language will be used to describe them. It will nevertheless be understood that no limitation of the scope of the disclosure is therefore intended. Such alterations and further modifications in the illustrated system, and such further applications of the principles of the disclosure as would normally occur to those skilled in the art are to be construed as being within the scope of the present disclosure. It will be understood by those skilled in the art that the foregoing general description and the following detailed description are exemplary and explanatory of the disclosure and are not intended to be restrictive thereof.

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

Unless otherwise defined, all technical and scientific terms used herein have the same meaning as commonly understood by those skilled in the art to which this disclosure belongs. The system, methods, and examples provided herein are only illustrative and not intended to be limiting.

Embodiments of the present disclosure provide a liquid-based thermal management system for a power supply unit for efficient removal of heat generated by high-power electrical and electronic components. The disclosure broadly provides a compact and scalable cooling arrangement in which heat is transferred directly from heat-generating components within the power supply unit to a liquid cooling structure through a short and efficient thermal path, thereby reducing localized hot spots and improving overall thermal performance. By integrating thermal interface materials, liquid-cooled conduits, and/or cold plates into existing shelf or rectifier shelf structures with minimal mechanical modification, the proposed power supply unit enables enhanced heat dissipation without reliance on bulky heat sinks or high-speed air-cooling devices. As a result, the disclosed liquid-based thermal management system efficiently removes heat from the power supply unit, enabling higher power density, enhanced thermal stability, and improved reliability, while extending operational life. The system is particularly advantageous in space-constrained and high-heat-flux environments, such as data centers, telecom installations, and high-performance computing systems.

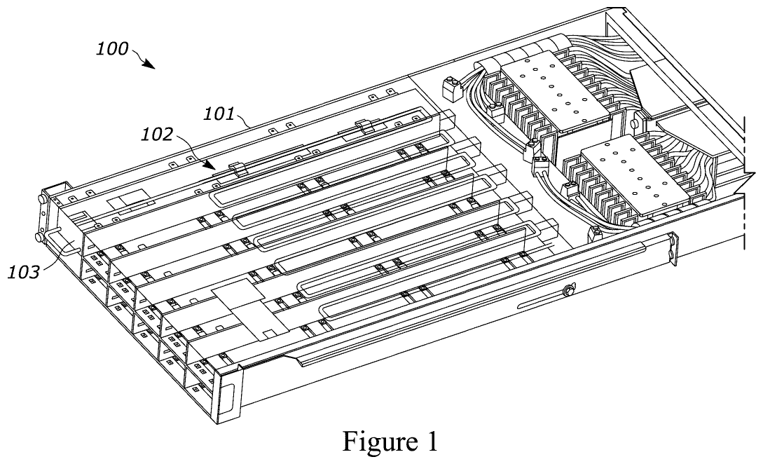

Referring now to the drawings, and more particularly to FIG. 1 through FIG. 5, where similar reference characters denote corresponding features consistently throughout the figures, there are shown preferred embodiments, and these embodiments are described in the context of the following exemplary system.

FIG. 1 illustrates a perspective view of a proposed liquid-based thermal management system for a power supply unit, in accordance with an embodiment of the present disclosure. The liquid-based thermal management system 100 for power supply unit 103 includes a shelf 101 and a liquid cooling adapter assembly 102. The shelf 100 is a structural support assembly adapted to house one or more power supply units 103. In the illustration, only one power supply unit 103 is shown for reference (with the understanding that shelf 100 may be adapted to support more than one power supply unit). The shelf 101 provides mechanical support, positional alignment, and thermal conduction for the power supply unit(s) 103 and associated electrical and electronic components housed therein. In one or more embodiments, the shelf 101 includes a substantially planar base and one or more vertical or horizontal surfaces defining an internal volume for accommodating power supply unit(s) 103.

The shelf 101 may include one or more rectifier shelves or compartments formed as part of the shelf structure, each rectifier shelf being adapted to receive rectifier modules containing heat-generating electrical and/or electronic components. The shelf 101 is preferably formed from a thermally conductive material, such as metal, to facilitate heat spreading and conduction away from localized thermal hot spots generated during operation of the power supply unit(s) 103.

Through its combined mechanical and thermal functions, the shelf 101 acts as an interface between the heat-generating components of the power supply unit 103 and the liquid-cooling adapter assembly 102, thereby enabling efficient heat transfer, compact integration, and improved thermal performance of the power supply unit 103.

The power supply unit 103 is configured to receive electrical input power and deliver conditioned output power to one or more electrical loads. In one or more embodiments, the power supply unit 103 is implemented as a rectifier module configured to convert alternating current (AC) power to direct current (DC) power, although other power conversion configurations may also be employed. The power supply unit 103 may include a plurality of electrical and/or electronic components, including power semiconductor devices, magnetic components, and control circuitry, which generate heat during normal operation.

The power supply unit 103 is housed within the shelf 101 that provides mechanical support, electrical interconnection, and thermal integration for the power supply unit 103. The shelf 101 is adapted to receive one or more power supply units 103 in a modular manner, enabling insertion, removal, and replacement of individual power supply units 103 without disturbing adjacent units. The shelf 101 further defines the spatial relationship between the power supply unit 103 and the liquid-cooling adapter assembly 102, thereby enabling efficient heat transfer from the power supply unit 103 to the liquid-cooling adapter assembly 102.

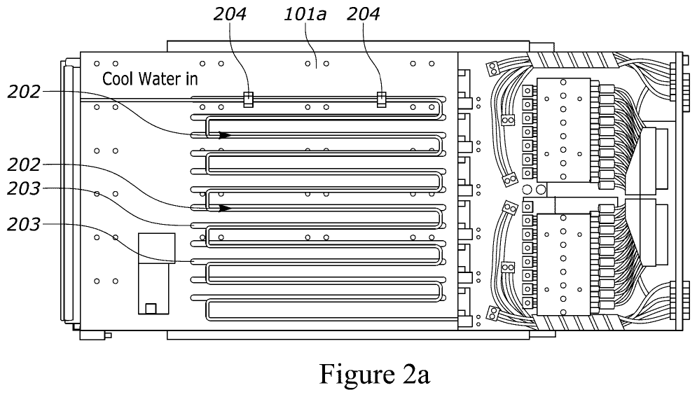

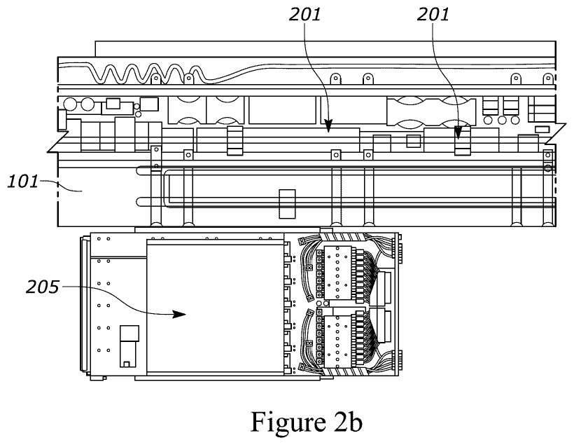

The system 100 is provided with a liquid-based thermal management capability to remove heat generated by high-power electrical and/or electronic components during the operation of the system 100. The liquid-based thermal management is performed by a liquid cooling adapter assembly 102 that is integrated with the shelf 101 of the system 100 and is arranged to establish an efficient thermal path between heat-generating components and a liquid coolant circulating through the heat-generating components. The shelf 101, liquid cooling adapter assembly 102, and power supply unit 103 are described in detail below with reference to FIGS. 2a and 2b.

FIGS. 2a and 2b illustrate a top view of a proposed liquid-based thermal management system for a power supply unit, in accordance with an embodiment of the present disclosure. In an aspect of this embodiment, the liquid cooling adapter assembly 102 includes at least one thermal interface material 201 positioned between selected heat-generating electrical and/or electronic components and a surface of the shelf 101. The thermal interface material 201 may be provided in the form of double-sided thermal tape. The thermal interface material 201 is configured to absorb heat from the components and conduct the heat to the shelf 101 with minimal thermal resistance, thereby reducing localized hot spots within the power supply unit 103.

In an aspect of this embodiment, the liquid cooling adapter assembly 102 further includes a plurality of liquid-carrying cooling conduits 202 arranged on a surface of the shelf 101, such as a top surface 101a. The liquid-carrying cooling conduits 202 are configured to carry a circulating liquid coolant and are thermally coupled to the shelf 101 so as to receive heat conducted through the shelf 101 from the heat-generating components. The liquid-carrying cooling conduits 202 include at least one inlet configured to receive a cooled liquid coolant and at least one outlet configured to discharge the liquid coolant after it has absorbed heat from the power supply unit. Circulation of the liquid coolant is driven by a pumping mechanism, not shown in FIG. 2a, such as an external or integrated pump, which establishes a continuous flow of the liquid coolant through the cooling conduits 202. During operation, the pump directs the cooled liquid coolant into the inlet, causing the coolant to absorb thermal energy while flowing along the cooling conduits 202 in thermal communication with the shelf 101. After absorbing thermal energy from the cooling conduits 202, the heated liquid coolant is expelled through the outlet and returned to a heat exchanger or cooling reservoir, where the coolant is cooled and recirculated into the inlet, thereby maintaining a closed-loop cooling path. This thermal energy exchange results in reducing the temperature of the cooling conduits 202 while increasing the temperature of the coolant circulating through the cooling conduits 202.

In an aspect, as shown in FIG. 2a, atop surface 101a of the shelf 101 is provided with embosses 203 to house and support the liquid-carrying cooling conduits 202 while enhancing thermal contact between the liquid-carrying cooling conduits 202 and the shelf 101. The liquid-carrying cooling conduits 202 may be mechanically retained on the shelf 101 using securing elements 204 such as clamps, and may optionally be covered by a protective enclosure 205 (shown in FIG. 2b) to shield the liquid-carrying cooling conduits 202 from external environmental exposure.

The liquid coolant used in the liquid-carrying cooling conduits 202 may include, but is not limited to, deionized water, mixtures of water and ethylene glycol, mixtures of water and propylene glycol, mineral oils, dielectric fluids, or other suitable cooling liquids. Circulation of the liquid coolant through the cooling conduits 202 enables continuous removal of heat from the shelf 101.

By integrating the liquid cooling adapter assembly 102 with the shelf 101, the liquid-based thermal management system 100 provides a compact and efficient cooling solution that minimizes the number of thermal interfaces and shortens the heat transfer path. This arrangement enables improved thermal performance, supports higher power density operation, reduces reliance on forced air cooling, and enhances the reliability and operational lifespan of the power supply unit 103, particularly in space-constrained and high-temperature operating environments.

By establishing a continuous thermal path from the power supply unit 103 to the shelf 101 and from the shelf 101 to the liquid-based thermal management system, the disclosed arrangement enables efficient removal of heat from the power supply unit 103 while minimizing reliance on forced air cooling. This integrated thermal architecture supports higher power density operation, reduces component temperatures, improves reliability, and extends the operational life of the power supply unit 103, particularly in compact and high-temperature operating environments.

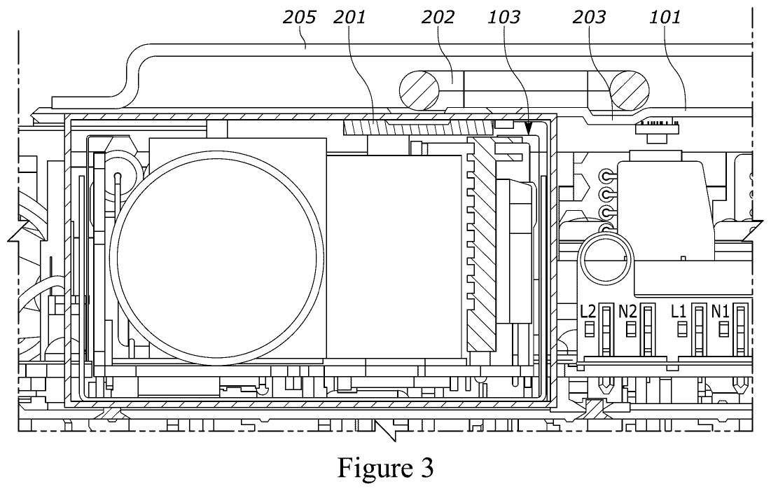

FIG. 3 illustrates a front sectional view of a proposed liquid-based thermal management system for a power supply unit, in accordance with an embodiment of the present disclosure. The front sectional view of the system 100 illustrates the relative arrangement and thermal coupling of the components previously described with reference to FIGS. 1 and 2. As shown in the sectional view, the power supply unit 103 is received within the shelf 101, with a plurality of heat-generating electrical and/or electronic components disposed therein. The thermal interface material 201 is positioned between selected heat-generating components of the power supply unit 103 and an adjacent surface (top surface) of the shelf 101, thereby establishing a direct thermal conduction path from the components to the shelf 101.

The shelf 101, formed from a thermal conductive material, is shown in thermal communication with the liquid-carrying cooling conduits 202. The plurality of liquid-carrying cooling conduits 202 is arranged along a surface (top surface) of the shelf 101 and is supported by structural features of the shelf 101, such as embosses 203, to enhance thermal contact and mechanical stability. The liquid-carrying cooling conduits 202 are secured to the shelf 101 using fastening or clamping elements 204 and are configured to carry a circulating liquid coolant.

In this sectional view, the thermal path from the heat-generating electrical and/or electronic components of the power supply unit 103, through the thermal interface material 201 and the shelf 101, and into the liquid-carrying cooling conduits 202 is clearly illustrated. Circulation of the liquid coolant through the cooling conduits 202 enables removal of heat from the shelf 101, thereby facilitating efficient liquid-based thermal management of the power supply unit 103.

Other embodiments may involve variations in thermally conductive interface materials, liquid cooling configurations, or mechanical fastening schemes used to integrate the liquid cooling adapter assembly with the shelf or rectifier shelf. Additional features, such as protective enclosures for liquid-carrying conduits, leak-mitigation structures, or enhanced liquid flow control components, may also be incorporated. The inventive concept encompasses a wide range of modifications, substitutions, and equivalents that maintain the principle of efficient heat transfer from heat-generating electrical and/or electronic components to a circulating liquid coolant through an integrated liquid-based thermal management architecture.

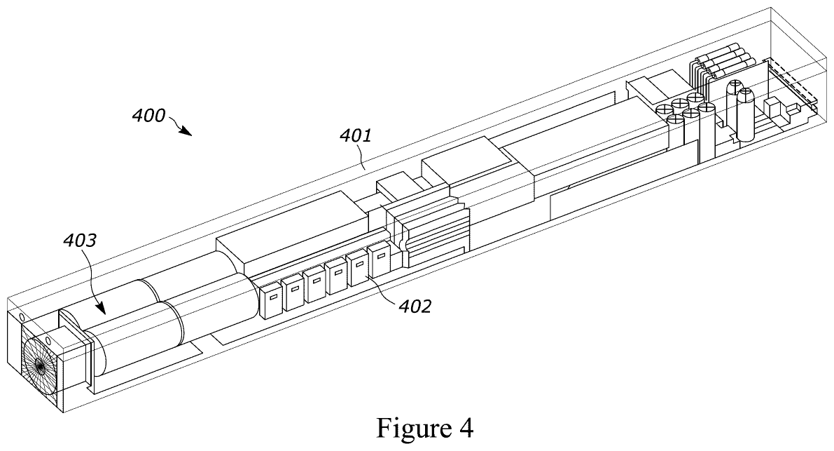

FIG. 4 illustrates a perspective view of a proposed liquid-based thermal management system for a power supply unit, in accordance with another embodiment of the present disclosure. In this embodiment, as illustrated in the corresponding perspective view, the liquid-based thermal management system 400 is implemented using one or more cold plates 401 integrated within a rectifier shelf 402 of the shelf 101. The general construction of the shelf 101 and the power supply unit 403 may be similar to that described with reference to FIGS. 1 and 2, and the following description focuses on the distinctions introduced by the cold plate arrangement.

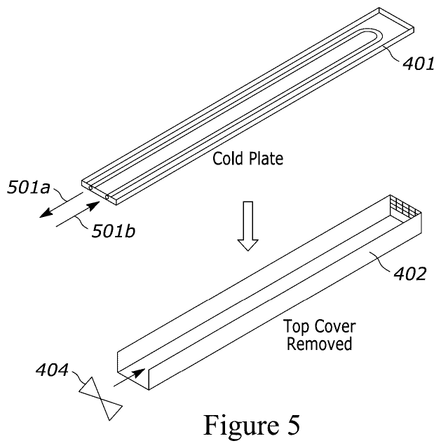

As shown in the perspective view, a plurality of heat-generating electrical and/or electronic components of the power supply unit 403 is disposed within the rectifier shelf 402. The cold plate 401 is arranged within the rectifier shelf 402 and positioned in thermal communication with the heat-generating components. In certain implementations, the cold plate 401 is placed in direct contact with selected components, while in other implementations one or more thermal interface material is interposed between the components and the cold plate 401 to facilitate efficient heat transfer. The details of the cold plate are discussed below with reference to FIG. 5.

FIG. 5 illustrates an exploded view of a proposed liquid-based thermal management system for a power supply unit, in accordance with another embodiment of the present disclosure. The cold plate 401 defines one or more internal channels 501a, 501b configured to receive and circulate a liquid coolant. The one or more internal channels 501a, 501b are fluidly coupled to at least one inlet port and at least one outlet port formed on the cold plate 401, wherein the inlet port is configured to receive a cooled liquid coolant from a liquid circulation system and the outlet port is configured to discharge the liquid coolant after the liquid coolant has absorbed heat from the cold plate 401. During operation, the liquid coolant flows through the internal channels 501a, 501b in thermal communication with the body of the cold plate 401, thereby absorbing heat transferred from one or more heat-generating electrical and/or electronic components positioned in thermal contact with the cold plate 401. The heated liquid coolant is then expelled through the outlet port and directed to a heat exchanger or cooling reservoir for cooling and recirculation, thereby maintaining a closed-loop liquid cooling path. In an aspect of this embodiment, the cold plate is fabricated from thermally conductive metal material, such as copper.

The liquid coolant used in the internal channels 501a, 502b of the cold plate 401 may include, but is not limited to, deionized water, mixtures of water and ethylene glycol, mixtures of water and propylene glycol, mineral oils, dielectric fluids, or other suitable cooling liquids. Circulation of the liquid coolant enables continuous removal of heat from the rectifier shelf 402.

In this embodiment, the cold plate 401 provides a localized liquid cooling structure within the rectifier shelf 402, thereby shortening the heat transfer path and reducing thermal resistance between the heat-generating components and the liquid coolant. This arrangement enables efficient removal of heat from high-power-density regions of the power supply unit 403 while maintaining a compact form factor and minimizing reliance on forced air cooling.

In an aspect of this embodiment, a fan assembly 404 may be provided at one end of rectifier shelf 402 to facilitate removal of residual heat from the power supply unit 403. The fan assembly 404 is configured to promote airflow across the power supply unit 403 and associated components, thereby supplementing the liquid-based thermal management provided by the cold plate 401. The fan assembly 404 may operate in conjunction with the cold plate 401 to enhance overall thermal performance, particularly under high ambient temperature or high load operating conditions.

In this embodiment, in addition to the cold plate 401 arrangement provided within the rectifier shelf 402, a plurality of liquid-carrying cooling conduits may also be provided on the shelf for supplemental heat removal. The liquid-carrying cooling conduits are arranged on a surface of the shelf and are thermally coupled thereto in a manner similar to that described with reference to the previously discussed embodiment. The construction, arrangement, and operation of the liquid-carrying cooling conduits, including their thermal coupling to the shelf and circulation of a liquid coolant therethrough, remain substantially the same as in the previously discussed embodiment and are therefore not discussed in further detail herein.

The disclosure offers several notable advantages that make it particularly suited for patent protection and commercial adoption in markets where thermal management of power supply units are critical. An advantage offered by the disclosed system is the substantial improvement in thermal management. By directly integrating liquid-carrying cooling pipes and/or cold plates with the shelf and/or rectifier shelf, the disclosure enables efficient removal of heat from high-temperature electrical and electronic components, thereby significantly reducing localized hot spots within the power supply unit. The use of thermal interface material establishes a short and continuous heat transfer path with fewer thermal interfaces, minimizing thermal resistance and enhancing overall heat dissipation efficiency. This direct conductive coupling eliminates the need for bulky heat sinks or specialized cooling modules, resulting in a compact, rigid, and robust configuration that is simple to implement and requires reduced assembly time.

Further, the improved thermal management allows the power supply unit to operate at higher power densities and increased power throughput while maintaining reliability, even under elevated operating temperatures. The proposed system is cost-effective, scalable, and well suited for modern data center environments where space constraints, high power ratings, and enhanced reliability are critical.

It will be understood that the foregoing description of preferred embodiments is illustrative and not intended to be limiting. Various changes or modifications in form, detail, or arrangement of parts, as well as other embodiments, may be made without departing from the spirit and scope of the disclosure. The scope of protection sought is defined exclusively by the claims appended hereto.

While specific examples of thermal interface materials, liquid-carrying cooling conduits, cold plates, coolant types, and circulation mechanisms have been described, it should be appreciated that equivalents, alternatives, or substitutions may be employed to achieve improved or alternative thermal performance, cooling efficiency, manufacturability, assembly, or system integration, as may be suited for particular power supply configurations, operating conditions, or cooling infrastructure requirements.

Reference in the specification to “one embodiment” or “an embodiment” means that a particular feature, structure, or characteristic described is included in at least one implementation of the disclosure. The appearances of such phrases in various places in the specification are not necessarily all referring to the same embodiment, nor are separate or alternative embodiments mutually exclusive of one another.

The terms and expressions used herein are employed as terms of description and not of limitation or exclusion, and there is no intent to exclude equivalents of any features or elements described. The disclosure has been described in language more or less specific as to structural features, it is to be understood, however, that the disclosure is not limited to the specific features shown or described, since the means and construction herein disclosed comprise preferred forms of putting the disclosure into effect.

Any combination of the above features and functionalities may be used in accordance with one or more embodiments. In the foregoing specification, embodiments have been described with reference to numerous specific details that may vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set as claimed in claims that issue from this application, in the specific form in which such claims issue, including any subsequent correction.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A liquid-based thermal management system for a power supply unit, the system comprising:
a shelf to house a power supply unit, the shelf being in thermal communication with at least one of a plurality of heat-generating components (components) of the power supply unit, the plurality of components comprising an electrical component, an electronic component and combinations thereof; and
a liquid cooling adapter assembly thermally coupled to the shelf, the liquid cooling adapter assembly comprising:
at least one thermal interface material disposed between at least one of the plurality of components and the shelf, wherein the thermal interface material is configured to conduct heat from the at least one of the plurality of components to the shelf; and
a plurality of liquid-carrying cooling conduits (conduits) arranged on the shelf to receive heat conducted through the shelf and to remove the heat by circulation of a liquid coolant.

2. The system as claimed in claim 1, wherein a top surface of the shelf comprises a plurality of embosses configured to secure the plurality of conduits to the shelf and to enhance thermal conduction between the shelf and the plurality of conduits.

3. The system as claimed in claim 1, wherein the shelf is constructed from a thermally conductive metal material.

4. The system as claimed in claim 1, wherein the plurality of conduits is mechanically retained on the shelf over the embosses using a fastening element or a clamping element.

5. The system as claimed in claim 1, wherein the liquid coolant comprises at least one of deionized water, a mixture of water and ethylene glycol, a mixture of water and propylene glycol, mineral oils, or a dielectric fluids.

6. The system as claimed in claim 1, wherein the plurality of conduits is covered by a protective enclosure.

7. The system as claimed in claim 1, wherein the thermal interface material comprises a double-sided thermal tape.

8. The system as claimed in claim 1, wherein the plurality of the conduits comprise an inlet port to receive a cooled liquid coolant and an outlet port to discharge the liquid coolant after the liquid coolant has absorbed heat from the shelf.

9. The system as claimed in claim 8, wherein circulation of the liquid coolant through the plurality of conduits is established by a pumping mechanism configured to drive the liquid coolant through the inlet port and the outlet port of the plurality of conduits.

10. A liquid-based thermal management system for power supply unit, the system comprising:
a shelf to house a rectifier shelf comprising a power supply unit, the rectifier shelf being in thermal communication with a plurality of heat-generating components (components) of the power supply unit, wherein the plurality of components is comprising an electrical component, an electronic component, or combinations thereof; and
a liquid cooling adapter assembly integrated within the rectifier shelf, the liquid cooling adapter assembly comprising:
cold plate disposed inside the rectifier shelf and positioned in thermal communication with at least one of the plurality of components, wherein the cold plate defines one or more internal channels configured to receive and circulate a liquid coolant therethrough;
wherein heat generated by the plurality of components is transferred to the cold plate and removed by the liquid coolant flowing through the one or more internal channels of the cold plate.

11. The system as claimed in claim 10, wherein the cold plate is in thermal communication with the plurality of components through a thermal interface material.

12. The system as claimed in claim 11, wherein the thermal interface material comprises a double-sided thermal tape.

13. The system as claimed in claim 10, wherein the liquid coolant comprises at least one of deionized water, a mixture of water and ethylene glycol, a mixture of water and propylene glycol, mineral oils, or a dielectric fluids.

14. The system as claimed in claim 10, wherein the cold plate is constructed from a thermally conductive metal material.

15. The system as claimed in claim 10, wherein the one or more internal channels of the cold plate comprises an inlet port to receive a cooled liquid coolant and an outlet port to discharge the liquid coolant after the liquid coolant absorbs heat from the shelf.

16. The system as claimed in claim 10, wherein circulation of the liquid coolant through the one or more internal channels of the cold plate is driven by a pumping mechanism configured to maintain continuous flow of the liquid coolant.
